(19) United States
(12) Patent Application Publication
(10) Pub. No.: US 2006/0162901 A1
(43) Pub. Date: Jul. 27, 2006

(54) Blower, cooling device including the blower, and electronic apparatus including the cooling device

(75) Inventors: Yoshimitu Aizono, Ogori-shi (JP); Shigeru Narakino, Fukutsu-shi (JP); Fuminori Hirakawa, Miyaki-gun (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/338,696

(22) Filed: Jan. 25, 2006

(30) Foreign Application Priority Data
Jan. 26, 2005 (JP) P2005-018080

(51) Int. Cl. H05K 7/20

(52) U.S. Cl. 165/80.4; 165/132; 165/104.33; 165/124; 361/697; 361/699

(57) ABSTRACT

The invention provides a cooling device including a heat-receiver integrated pump that has a heat-receiving part provided on one side thereof and delivers toward a connecting pipe liquid refrigerant on which a heat exchange has been performed through the heat-receiving part. A first radiator having a plurality of radiation fins radiates heat by exchanging heat with the liquid refrigerant sent via the connecting pipe. A second radiator having a plurality of radiation fins radiates heat by exchanging heat with the liquid refrigerant similarly to the first radiator. A fan blows air toward the first radiator and the second radiator. A base, constituting a fan casing, regulates an air-blowing direction of the fan, and includes a fan cover and a reserve tank. Liquid refrigerant within the reserve tank is thermally connected to a member forming an air-blowing path of the fan.

### BACKGROUND OF THE INVENTION

1. Field of the Invention

The present invention relates to a cooling device used for a cooling system using heat pipes or for a liquid cooling system that performs forced circulation of liquid refrigerant by using a pump for the purpose of forced cooling of various heating elements, such as a central processing unit (hereinafter referred to as CPU), chipsets, a display controller, an HDD, etc. that are arranged within a housing of an electronic apparatus, and an electronic apparatus including the cooling device.

2. Description of the Related Art

The movement toward improvement in the speed of data processing in recently developed computers is very rapid, and the clock frequency of CPUs is becoming markedly fast as compared with before. As a result, the calorific value of the CPUs increases. In addition to a method of bringing heat sinks or heat radiation fins serving as heat-radiating parts into contact with heating elements to radiate heat like before, a method of directly cooling heat sinks using a fan, a method of blowing air toward heat-radiating parts by a fan to cool them in a heat sink module in which a heat-receiving part is thermally connected to the heat-radiating parts via heat pipes, or a liquid cooling method in which highly conductive liquid refrigerant is forcedly circulated by a pump to transport heat from a heat-receiving part to a heat-radiating part and heat exchange is performed in each of the heat-receiving part and the heat-radiating part become indispensable. It is necessary to improve the cooling capacity and reduce the size and weight in future. Moreover, the necessity for cooling various associated parts, such as chipsets, a display controller, and an HDD, except the CPU is also increasing with the rise in clock frequency to improve the performance of a display device of a computer or improve the accessibility to a memory.

Thus, as a cooling device that radiates the heat generated from a heating element mounted on an electronic apparatus, there is known, for example, a cooling device as disclosed in JP-A-7-142886 (page 6, FIG. 1), in which the highly thermal conductive liquid refrigerant in a heat receiver thermally connected to the heating element is forcedly circulated in liquid by a pump to transport heat from a heat-receiving part to a heat-radiating part, thereby radiating heat.

FIG. 9 illustrates the entire structure of an electronic apparatus incorporating the cooling device. Referring to this figure, a keyboard 103 is accommodated in a top face of a first housing 101 of the electronic apparatus, and a wiring board 102 having a plurality of semiconductor elements mounted thereon, a disk drive 106, etc. are accommodated within the first housing below the keyboard. Further, a display device 108 is accommodated within a second housing 107. Among the semiconductor elements mounted on the wiring board 102, a semiconductor element 104 having a particularly high calorific value is cooled by a cooling device composed of a heat receiver 105, a radiator 109, a flexible tube 111, etc. Each of the heat receiver 105 and the radiator 109 has liquid channels formed therein, and has liquid refrigerant enclosed therein. Moreover, the radiator 109 has a liquid-driving unit incorporated therein. The liquid refrigerant is driven between the heat receiver 105 and the radiator 109 by the liquid driving unit. Specifically, the heat generated in the semiconductor element 104 is exchanged with the liquid refrigerant via the heat receiver 105, passes through the flexible tube 111, and is thermally transported to the radiator 109. Further, in the heat-radiating part, the radiator 109 is thermally and physically attached to a metallic second housing 107 directly by screws 110. Thus, heat is widely diffused in walls of the second housing by high thermal conductivity of the second housing 107. Therefore, the semiconductor element 104 can be efficiently cooled.

However, the reserve tank that reserves liquid refrigerant is generally provided near the radiator that constitutes the heat-radiating part of such a cooling device. In this case, if the reserve tank is provided only for the purpose of reserving the liquid refrigerant in advance in order to compensate a decrease in the amount of the liquid caused by evaporation of the moisture in the liquid refrigerant, the reserve tank may be disposed in any place as long as it is within a circulating path for the liquid refrigerant. However, since the reserve tank itself has a significantly large thermal capacity and also a heat storage property, it is not suitable for heat transportation. Therefore, the reserve tank is not disposed between the radiator and the heat receiver, which are thermally connected to the heating element, but it is preferably disposed in a path where the liquid refrigerant has once completed heat transportation and returns to the heat receiver again, that is, in a portion of the path where liquid refrigerant is transported from the radiator to the heat receiver. That is, since the temperature of the liquid refrigerant itself when it is returned to the heat receiver is preferably as low as possible, in order to suppress a rise in temperature of the liquid refrigerant to be reserved within the reserve tank, it is preferable that the reserve tank be disposed in a place where ambient temperature does not rise comparatively even within an electronic apparatus, or that the reserve tank be disposed as away as possible from a mounting board of an electronic circuit, on which a heating element, such as a CPU, is mounted. For example, as previously mentioned, it is necessary to dispose the reserve tank within a second housing to accommodate a display device while avoiding disposing the reserve tank within a first housing of the electronic apparatus on which a keyboard is mounted. In addition, when liquid refrigerant circulates without securing a sufficient size of the radiator that requires a comparatively large occupying volume in relation to the space in the electronic apparatus, the exhaust direction, etc. nor performing heat exchange between the liquid refrigerant that has transported heat and the radiator, the liquid refrigerant within the reserve tank rises in temperature similarly. As a result, the cooling performance is deteriorated.

Moreover, since connecting pipes, such as flexible tubes, between the heat receiver and the radiator and between the reserve tank and the pump becomes long inevitably, and the evaporation amount of the moisture within the liquid refrigerant increases as much, a new problem occurs in that the volume of the reserve tank reserving liquid refrigerant in advance in order to compensate the decrease in the amount of the liquid should also be set large and an improvement in the cooling performance and miniaturization of the cooling device are not well compatible with each other.

### SUMMARY OF THE INVENTION

The invention has been made to solve such conventional problems. It is therefore an object of the invention to improve cooling performance and make a cooling device small.

In order to achieve the above object, the invention provides a cooling device that circulates liquid refrigerant and takes heat from a heating element mounted on a board by exchange of heat with the liquid refrigerant to radiate the taken heat. The cooling device includes a heat-receiving part thermally connected to the heating element; a pump that delivers toward a connecting pipe the liquid refrigerant on which heat exchange has been performed through the heat-receiving part; a radiator having a plurality of radiation fins that radiate heat by exchanging heat with the liquid refrigerant sent via the connecting pipe; a fan that blows air toward the radiator; a fan casing that regulates an air-blowing direction of the fan; and a reserve tank that reserves the liquid refrigerant. The liquid refrigerant within the reserve tank is thermally connected to a member forming an air-blowing path of the fan.

According to the aspects of the invention, the cooling device includes a heat-receiving part thermally connected to the heating element; a pump that delivers toward a connecting pipe the liquid refrigerant on which heat exchange has been performed through the heat-receiving part; a radiator having a plurality of radiation fins that radiate heat by exchanging heat with the liquid refrigerant sent via the connecting pipe; a fan that blows air toward the radiator; a fan casing that regulates an air-blowing direction of the fan; and a reserve tank that reserves the liquid refrigerant. The liquid refrigerant within the reserve tank is thermally connected to a member forming an air-blowing path of the fan. Thus, the air outside the cooling device that has been sucked from above or below the fan comes into direct contact with the member forming an air-blowing path of the fan, and heat radiation is performed by heat exchange in the member. Therefore, the heat can be finally radiated to the outside by air-blowing of the fan. As a result, a rise in temperature of the liquid refrigerant within the reserve tank can be suppressed.

Accordingly, when the radiator, the fan, the reserve tank, etc. that constitute a heat-radiating part are installed near the heating element or in a place where ambient temperature is relatively high, or even when a radiator that cannot ensure a satisfactory heat radiation property is used, the cooling performance of the cooling device is rarely damaged. In addition, the length between the heat-receiving part and the radiator and the length between the reserve tank and the heat-receiving part can be reduced. Therefore, the calorific value of the liquid refrigerant becomes small and thus the capacity of the reserve tank can also be set small as much. As a result, the whole cooling device can also be easily made small.

According to a first aspect of the invention, there is provided a cooling device that circulates liquid refrigerant and takes heat from a heating element mounted on a board by exchange of heat with the liquid refrigerant to radiate the taken heat. The cooling device includes a heat-receiving part thermally connected to the heating element; a pump that delivers toward a connecting pipe the liquid refrigerant on which heat exchange has been performed through the heat-receiving part; a radiator having a plurality of radiation fins that radiate heat by exchanging heat with the liquid refrigerant sent via the connecting pipe; a fan that blows air toward the radiator; a fan casing that regulates an air-blowing direction of the fan; and a reserve tank that reserves the liquid refrigerant. The liquid refrigerant within the reserve tank is thermally connected to a member forming an air-blowing path of the fan. Thus, the air outside the cooling device that has been sucked from above or below the fan comes into direct contact with the member forming an air-blowing path of the fan, for example, a fan casing accommodating a fan and a radiator having a plurality of radiation fins, and heat radiation is performed by heat exchange in the member. Therefore, the heat can be finally radiated to the outside by air-blowing of the fan. As a result, a rise in temperature of the liquid refrigerant within the reserve tank can be suppressed as compared with the conventional cooling device. Accordingly, when the radiator, the fan, the reserve tank, etc. that constitute a heat-radiating part are installed near the heating element or in a place where ambient temperature is relatively high, or even when a radiator that cannot ensure a satisfactory heat radiation property is used, the cooling performance of the cooling device is rarely damaged.

In addition, a connecting pipe between the heat-receiving part and the radiator and a connecting pipe between the reserve tank and the heat-receiving part can also be set short, the evaporation of the moisture in the liquid refrigerant from the connecting pipes can be relieved as much, and the capacity of the reserve tank reserving the liquid refrigerant in advance by the amount reduced by the moisture evaporation can also be set small. As a result, the whole cooling device can also be easily made small.

Here, the member forming an air-blowing path of the fan is not limited to only the fan casing and the radiator. For example, after a duct to form an air-blowing path of the fan is separately provided between the fan casing and the radiator or on the exhaust side of the radiator, etc, the heating element may be thermally connected to the duct.

According to a second aspect of the invention, there is provided a cooling device that circulates liquid refrigerant and takes heat from a heating element mounted on a board by exchange of heat with the liquid refrigerant to radiate the taken heat. The cooling device includes a heat-receiver integrated pump that has a heat-receiving part thermally connected to the heating element provided on one side thereof and delivers toward a connecting pipe the liquid refrigerant on which heat exchange has been performed through the heat-receiving part; a radiator having a plurality of radiation fins that radiate heat by exchanging heat with the liquid refrigerant sent via the connecting pipe; a fan that blows air toward the radiator; a fan casing that regulates an air-blowing direction of the fan; and a reserve tank that reserves the liquid refrigerant. The liquid refrigerant within the reserve tank is thermally connected to a member forming an air-blowing path of the fan. Thus, in addition to the above-mentioned effects according to the first aspect, the number of components can be reduced because the heat-receiving part and the pump are integral. Therefore, the whole cooling device can be more easily made small. As a result, mounting of the components to a narrow space within an electronic apparatus is also possible.

According to a third aspect of the invention, a highly thermal conductive metallic member is used for a thermal connection part between the liquid refrigerant within the reserve tank and the member forming an air-blowing path of the fan. Thus, the conductivity of heat from the liquid refrigerant within the reserve tank to the fan casing to form an air-blowing path of the fan, the radiator, or the separately provided duct is further improved. This can promote heat exchange to improve the heat radiation property.

According to a fourth aspect of the invention, the reserve tank constitutes a portion of the member forming an air-blowing path of the fan. Thus, the thermal connectivity between the liquid refrigerant within the reserve tank and the fan casing to form an air-blowing path of the fan, the radiator, or the separately provided duct becomes easier. This can not only improve the cooling performance of the cooling device but also reduce the number of components. Therefore, the whole cooling device can be more easily made small as well as manufacture of the cooling device becomes easy.

According to a fifth aspect of the invention, a partition plate to form a bypass channel for the liquid refrigerant is provided within the reserve tank. Thus, stagnation of the liquid refrigerant within the reserve tank can be prevented, thereby promoting heat exchange and reducing heat storage effects. This can improve the heat radiation property of the cooling device as much.

According to a sixth aspect of the invention, heat-receiving fins are provided within the reserve tank, and the heat-receiving fins are thermally connected to the member forming an air-blowing path of the fan. Thus, the area of contact against the liquid refrigerant within the reserve tank can be increased by the heat-receiving fins arranged in predetermined positions within the reserve tank, and the conductivity of heat between the liquid refrigerant within the reserve tank and the fan casing to form an air-blowing path of the fan, the radiator, or the separately provided duct, which are thermally connected to the liquid refrigerant, is further improved. This can promote heat exchange to improve the heat radiation property.

According to a seventh aspect of the invention, the flow directions of the air and liquid refrigerant that simultaneously touch all or a part of the member of the reserve tank to form an air-blowing path of the fan are opposite to each other. Thus, within the reserve tank, a relatively high temperature of liquid refrigerant exchanges heat with a larger amount of blowing air. Therefore, heat radiation can be performed efficiently.

According to an eighth aspect of the invention, there is provided an electronic apparatus including any one of the above cooling devices. According to the third aspect, the cooling performance within the electronic apparatus is improved. As a result, the processing capability of a CPU, etc. mounted on the electronic apparatus can be improved and the stability of the operating state of the electronic apparatus can be ensured. In addition, this can also contribute to making the electronic apparatus small, slim and light-weight.

### BRIEF DESCRIPTION OF THE DRAWINGS

FIG. 1 illustrates the entire structure of an electronic apparatus incorporating a cooling device according to a first embodiment of the invention.

FIG. 2 is a perspective view of the cooling device according to the first embodiment of the invention.

FIG. 3 is a perspective view of the cooling device according to the first embodiment of the invention, with its fan cover removed.

FIG. 4 is a plan view of the cooling device according to the first embodiment of the invention, with its fan cover removed.

FIG. 5 is a plan view of a cooling device according to a second embodiment of the invention.

FIG. 6A is a plan view of a reserve tank having a partition plate provided therein, and FIG. 6B is a plan view of a reserve tank having one or a plurality of heat-receiving plates provided therein, of which a portion is cut away.

FIG. 7 illustrates the entire structure of an electronic apparatus incorporating a cooling device according to a third embodiment of the invention.

FIG. 8 illustrates the entire structure of an electronic apparatus incorporating a cooling device according to a fourth embodiment of the invention.

FIG. 9 illustrates the entire structure of an electronic apparatus incorporating a conventional cooling device.

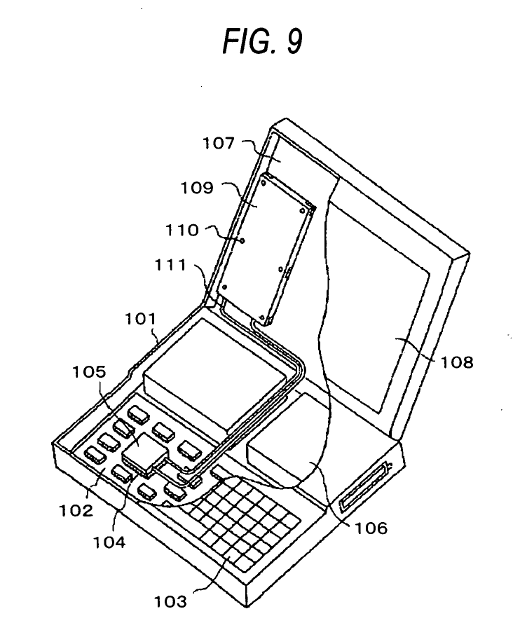

### DESCRIPTION OF THE PREFERRED EMBODIMENTS

Preferred embodiments of the invention relate to a liquid-cooling-type cooling device using liquid refrigerant, to be mounted on a notebook computer as an electronic apparatus, and they will be described below with reference to the drawings.

### First Embodiment

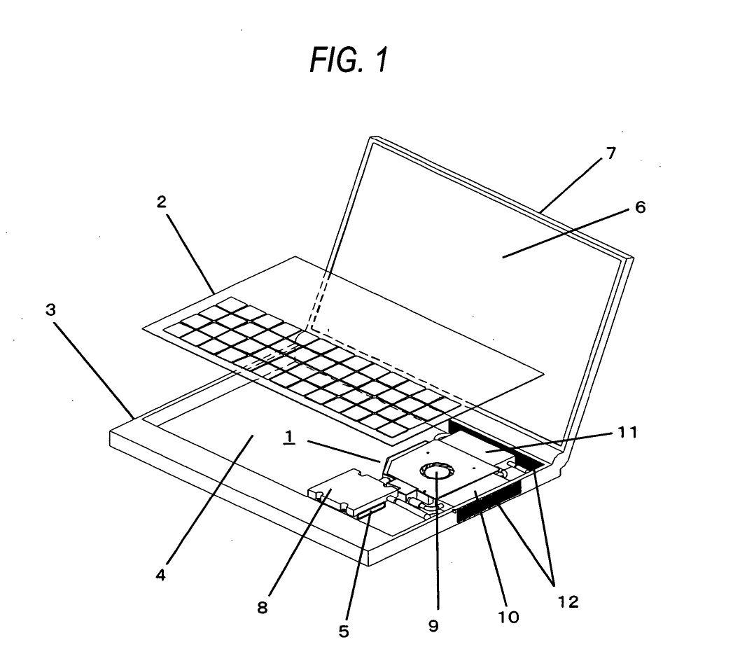

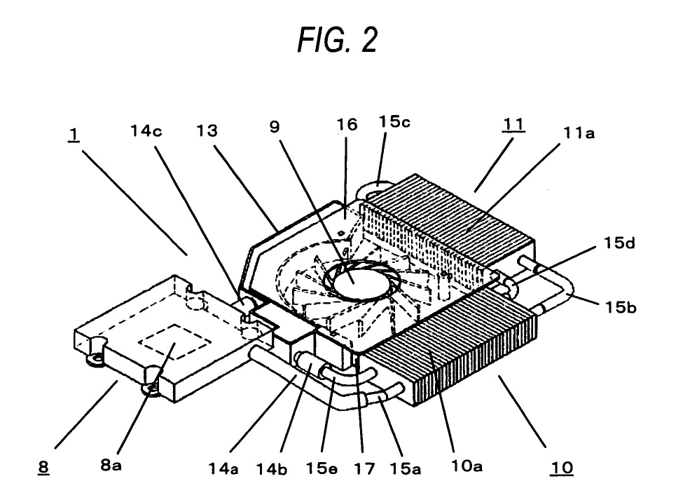

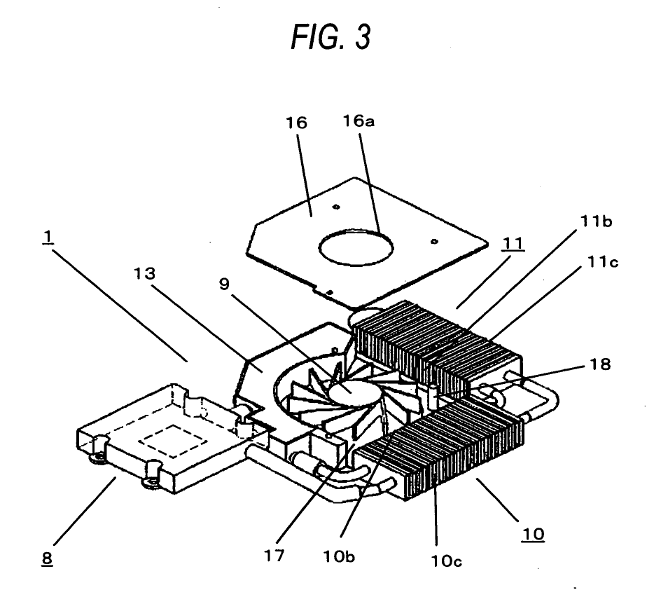

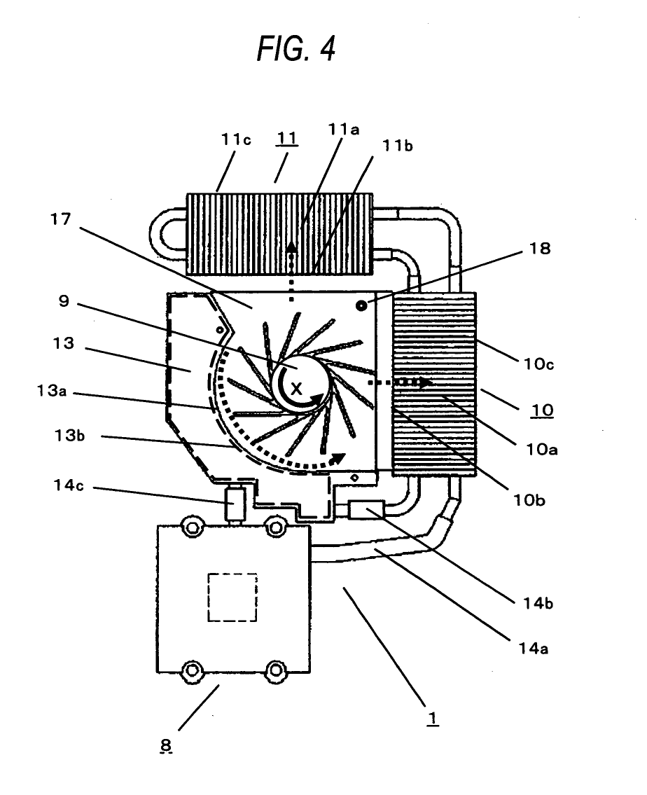

In FIGS. 1 to 4, FIG. 1 illustrates the entire structure of an electronic apparatus incorporating a cooling device according to A first embodiment of the invention, FIG. 2 is a perspective view of the cooling device according to The first embodiment of the invention, FIG. 3 is a perspective view of the cooling device according to the first embodiment of the invention, with its fan cover removed, and FIG. 4 is a plan view of the cooling device according to the first embodiment of the invention, with its fan cover removed.

First, FIG. 1 illustrates the entire structure of an electronic apparatus incorporating a cooling device 1. In this figure, the electronic apparatus is shown, with a keyboard 2 slightly floated from its regular position in order to more easily understand the inner structure thereof.

The electronic apparatus includes a first housing 3 of the electronic apparatus having a keyboard 2 mounted on its top face, a heating element 5 having a particularly large calorific value, such as a CPU mounted on an electronic circuit board 4 that is received within the first housing 3 and on which electronic components, etc. are arranged, a second housing 7 of the electronic apparatus having a display device 6 that displays processing results by the CPU, and a heat-receiver integrated pump 8 that is allowed to have a heat-receiving function by making the bottom face of a pump casing of a Wesco-type vortex pump flat and that serves as both functions of a pump and a heat receiver by providing liquid channels in the pump. This pump is directly placed on the heating element 5, such as a CPU.

In this case, the casing of the heat-receiver integrated pump 8 is made of highly thermal conductive, metallic material, such as metal, including aluminum and copper, and alloy. Also, the pump can be easily placed on the top face of the heating element 5, such as a CPU, by forming the bottom face of the pump into a flat face appropriately according to the size of the heating element 5. Accordingly, sufficient heat transfer can be performed.

That is, the heat-receiver integrated pump 8 comes into close contact with the heating element 5 to receive the heat therefrom and cool the heating element 5 while performing heat exchange with the liquid refrigerant flowing through the internal liquid channels.

On the other hand, although described later in detail, in the cooling device 1 disposed at a corner of the electronic apparatus, in order to radiate the heat transported by the liquid refrigerant into the air outside the electronic apparatus, air is blown toward two radiators 10 and 11, which are arranged in the shape of the letter “L”, by a thin fan 9, and the air that has passed through the radiators 10 and 11 is discharged from two vent holes 12 provided in a corner of the first housing 3.

As shown in FIG. 2, the cooling device 1 according to the first embodiment of the invention is a liquid-cooling-type cooling device using liquid refrigerant and including, as main components, the heat-receiver integrated pump 8 having a heat-receiving part 8a provided on its one face, the fan 9, the radiator 10, the radiator 11, and a reserve tank 13.

The bottom of the heat-receiver integrated pump 8 is provided with the heat-receiving part 8a, as indicated by broken lines, which is thermally connected to a heating element (not shown), and the heating element at high temperature exchanges heat with the liquid refrigerant that flows through the liquid channels, which are formed in the heat-receiver integrated pump 8, via the heat-receiving part 8a.

Moreover, the heat-receiver integrated pump 8 performs the operation that forcedly delivers the liquid refrigerant on which heat exchange has been performed by an action of a built-in pump (not shown) toward a connecting pipe 14a, such as a flexible tube.

Next, the liquid refrigerant delivered from the heat-receiver integrated pump 8 passes through a metal pipe 15a joined to the radiator 10, via the connecting pipe 14a. After the liquid refrigerant has passed through the inside of the radiator 10 having a plurality of radiation fins 10a, it passes through a metal pipe 15b joined to each of the radiator 10 and the radiator 11. Further, the liquid refrigerant passes through the inside of the radiator 11 having a plurality of radiation fins 11a and turns back by a metal pipe 15c. Then, the liquid refrigerant passes through a metal pipe 15d, passes through the radiator 10 again, passes through a connecting pipe 14b, such as a flexible tube, from a metal pipe 15e, and is sent into the reserve tank 13.

That is, while the liquid refrigerant, on which heat exchange is performed and of which temperature is elevated, transports heat in the order of the metal pipe 15a→the pipe 15b→the pipe 15c→the pipe 15d→the pipe 15e, which are joined to each radiator, and thus the liquid refrigerant carries out heat exchange sequentially between the radiator 10 and the radiator 11, heat is radiated repeatedly.

Then, while the liquid refrigerant that has completed the heat exchange with the radiator 10 and the radiator 11 is mixed with the liquid refrigerant in the reserve tank 13 already reserved, the liquid refrigerant having the same amount as that of the liquid refrigerant that has been sent into the reserve tank passes through the connecting pipe 14c, such as a flexible tube, and returns to the heat-receiver integrated pump 8.

That is, the liquid refrigerant in the cooling device 1 circulates continuously through the path of the heat-receiver integrated pump 8→the radiator 10→the radiator 11→the radiator 10→the reserve tank 13→the heat-receiver integrated pump 8, which are main components of the cooling device 1 as described above. Also, the liquid refrigerant is cooled by repeating the heat-receiving action in the heat-receiving part 8a of the heat-receiver integrated pump 8 and the heat radiation action in the radiator 10 and the radiator 11, and by forcedly radiating heat from the heating element thermally connected to the heat-receiving part 8a.

Next, referring to a perspective view of FIG. 3 showing the cooling device according to the first embodiment of the invention, with its fan cover 16 removed, the fan 9 is disposed in a predetermined position above a base 17, the reserve tank 13 is disposed in a peripheral position of the fan, and the fan cover 16 is placed on the top face of the reserve tank 13 and a support column 18. Since the air sucked from a suction port 16a of the fan cover 16 has its air-blowing direction regulated by the base 17, the reserve tank 13, and the fan cover 16 that constitute the fan casing, the air is sent toward an exhaust surface 10c from an intake surface 10b that is an air-blowing direction of the radiator 10 or toward an exhaust surface 11c from an intake surface 11b that is an air-blowing direction of the radiator 11, and is finally exhausted to the outside.

Further, a box portion of the reserve tank 13 is integrally formed with the base 17, and the fan cover 16 can also serve as a lid of the reserve tank 13.

Referring to the plan view of FIG. 4 showing the cooling device according to the first embodiment of the invention, with its fan cover 16 removed, the fan 9 is disposed in a position where the ventilation direction of the radiator 10 having the radiation fins 10a and the ventilation direction of the radiator 11 having the radiation fins 11a are approximately orthogonal to each other, and the fan 9 axially rotates in the direction of solid-line arrow X. Thus, a portion of the air sucked from the suction port 16a (refer to FIG. 3) of the fan cover 16 is directly blown toward each of the radiator 10 and the radiator 11 from the fan 9, as indicated by a linear broken-line arrow.

On the other hand, since another portion of the air sucked from the suction port 16a of the fan cover 16 attached to an upper portion of the fan 9 is first blown in the centrifugal direction of the fan 9, and has its air-blowing direction regulated by the fan casing composed of the base 17, the reserve tank 13, and the fan cover 16, it is delivered as indicated by curved broken-line arrow while colliding against an inner wall of the base 17, an outer wall 13a of the reserve tank 13 that faces the fan 9 in a peripheral direction of the fan 9, and an inner wall of the fan cover 16, and is finally blown toward the intake surface 10b of the radiator 10 and the intake surface 11b of the radiator 11.

Here, since the outer wall 13a of the reserve tank 13 is configured such that a portion of the outer wall facing blades of the fan 9 is in the shape of a circular arc and portions of the outer wall facing the intake surfaces 10b and 11b of the radiators 10 and 11 are formed in the direction that air is blown toward the intake surfaces 10b and 11b, thereby forming an air-blowing path of the fan 9, and the outer wall is thermally connected to the internal liquid refrigerant, a portion of the external air sucked from the suction port 16a of the fan cover 16 directly contacts the outer wall 13a of the reserve tank 13 that is a member forming an air-blowing path of the fan 9, where heat radiation is performed by heat exchange. As a result, the temperature rise of a liquid medium within an inner wall 13b of the reserve tank 13, as indicated by broken lines, is suppressed. That is, when the radiator 10, the radiator 11, the fan 9, the reserve tank 13, etc. that constitute a heat-radiating part are installed near the heating element or in a place where ambient temperature is relatively high, or even when a radiator that cannot ensure a satisfactory heat radiation property in relation to the space within an electronic apparatus for which the cooling device is used, sufficient cooling performance can be obtained.

In addition, since the connecting pipe 14a between the heat-receiver integrated pump 8 and the radiator 10 and the connecting pipe 14c between the reserve tank 13 and the heat-receiver integrated pump 8 become short, the capacity of the reserve tank 13 can also be set small as much, and the whole cooling device can also be easily made small, slim and light-weight.

Moreover, although it is preferable that the whole reserve rank 13 be made of highly thermal conductive metal, the structure of the reserve tank becomes more complicated, for example, if a gas-liquid separating part that does not cause air lock is built therein. Thus, the reserve tank may be fabricated in combination with a resin-molded part having good moldability and capable of coping with cost reduction, by an insert-integrated mold in which a highly thermal conductive, metallic member is incorporated in only an air-blowing path forming part, or the whole reserve tank may be fabricated of resin material for easiness in manufacture and weight saving, although it is a little inferior in terms of thermal conductivity.

### Second Embodiment

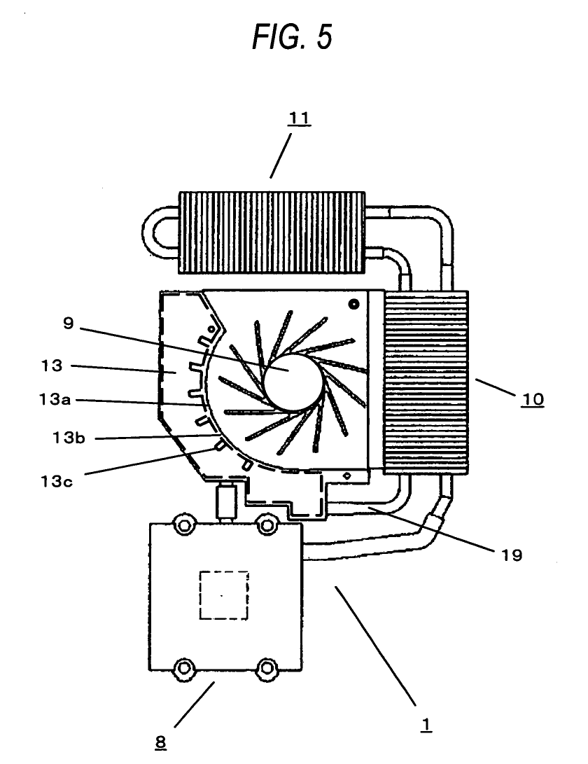

FIG. 5 is a plan view of a cooling device according to a second embodiment of the invention. Referring to this figure, a plurality of heat-receiving fins 13c are formed on an inner wall 13b of a reserve tank 13 on the side where an air-blowing path is to be formed. Here, it is preferable that the heat-receiving fins 13c be fabricated of highly thermal conductive metal member, for example, metallic material, such as aluminum and copper. Also, since the heat-receiving fins 13c can further increase the area to be in contact with the liquid refrigerant within the reserve tank 13, the conductivity of heat from the liquid refrigerant to the outer wall 13a of the reserve tank 13 forming an air-blowing path of the fan 9 can be improved. Therefore, the heat radiation property of the cooling device can be further enhanced.

Moreover, a thermal connection is also established between the reserve tank 13 and the radiator 10 forming an air-blowing path of the fan 9 by a connecting member 19 fabricated of highly thermal conductive metallic material, so that the conductivity of heat from the liquid refrigerant to the radiator 10 can also be improved, which can lead to synergistic effects, thereby improving the property of radiation of heat from the reserve tank 13.

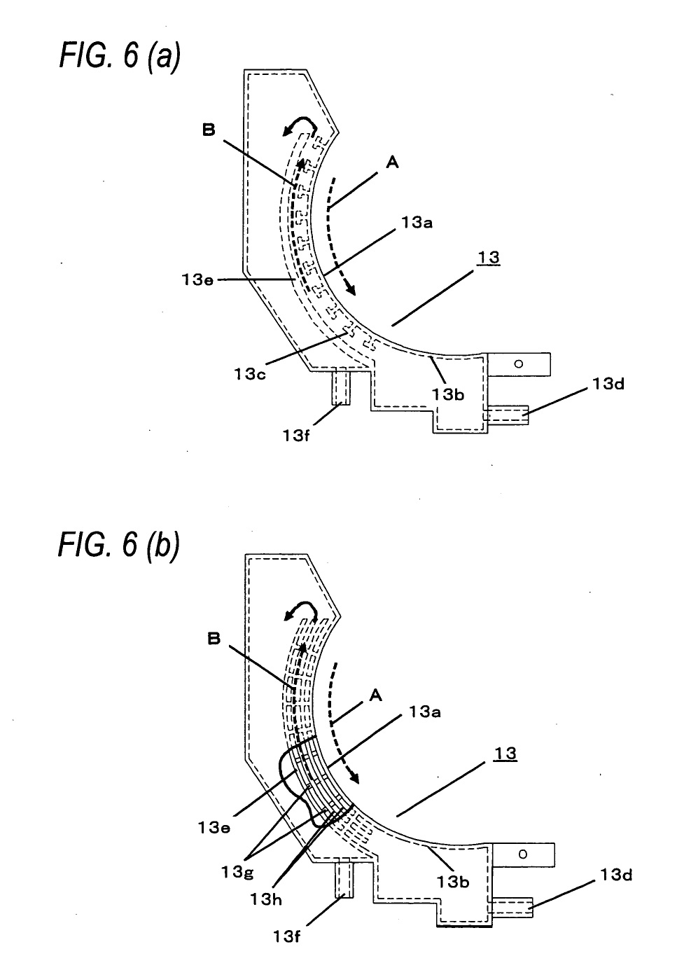

As another structure that improve the conductivity of heat between the liquid refrigerant within the reserve tank 13 and the outer wall 13a of the reserve tank 13 forming an air-blowing path of the fan 9, referring to the plan view of FIG. 6A showing a reserve tank having a partition plate provided therein, one or a plurality of T-shaped heat-receiving fins 13c is/are provided on the inner wall 13b of the reserve tank 13 on the side where an air-blowing path is to be formed, and a bypass channel is formed by providing a circular-arc partition plate 13e that extends approximately parallel to the outer wall 13a from a portion of the inner wall 13b of the reserve tank 13 close to a suction port 13d to an opposite end thereof so that the liquid refrigerant is allowed to go around within the reserve tank 13, as indicated by the broken-line arrow and to flow out of a discharge port 13f. Accordingly, stagnation of the liquid refrigerant within the reserve tank 13 can be prevented, thereby reducing heat storage effects, and the surface area of the heat-receiving fins 13c that have contacted the liquid refrigerant can be increased, thereby further promoting heat exchange with the outer wall 13a of the reserve tank 13. Thus, the heat radiation property of the cooling device can be further improved. In this case, if the flow direction (broken-line arrow A) of the air in contact with the outer wall 13a of the reserve tank 13 on the side where an air-blowing path of the fan 9 is to be formed and the flow direction (broken-line arrow B) of the liquid refrigerant in contact with the inner wall 13b of the reserve tank are opposite to each other as shown in FIG. 5, not only a relatively high temperature of the liquid medium in the reserve tank 13 exchanges heat with a greater amount of blowing air, but also the speed of the liquid medium relative to the flow of air can be increased. Therefore, heat radiation can be efficiently performed. In addition, when the flow direction of the air is merely opposite to the flow direction of the liquid refrigerant without forming any bypass channel, the suction port 13d may be provided at a leeward end of the reserve tank 13 in the air flow direction, and the discharge port 13f may be formed at the other windward end.

Further, referring to the plan view of FIG. 6B showing a reserve tank provided with one or a plurality of heat-receiving plates, of which a portion is cut away, a bypass channel is formed by providing a partition plate 13e that extends from a portion of the inner wall 13b of the reserve tank 13 close to the suction port 13d to the vicinity of the opposite end thereof, and one or a plurality of heat-receiving plates 13h that is/are curved to almost the same extent as the outer wall 13a of the reserve tank 13 on the side of the fan 9 (FIG. 5) is/are juxtaposed in an intermediate portion where the inner wall 13b of the reserve tank 13 on the side where an air-blowing path is to be formed and the partition plate 13e are connected to each other by a connecting body 13g, and the liquid refrigerant is brought into contact with the heat-receiving plate 13b such that it is allowed to go around within the reserve thank 13, as indicated by the broken-line arrow, and to flow to the discharge port 13f. Accordingly, stagnation of the liquid refrigerant within the reserve tank 13 can be prevented, thereby reducing heat storage effects, and the area of contact between the liquid refrigerant and the heat-receiving plate 13h is very large. Thus, heat exchange between the liquid refrigerant and the outer wall 13a of the reserve tank 13 forming an air-blowing path of the fan 9 can be more efficiently performed. Even in this case, it is preferable that the flow direction (broken-line arrow A) of the air in contact with the outer wall 13a of the reserve tank 13 on the side where an air-blowing path of the fan 9 is to be formed and the flow direction (broken-line arrow B of the liquid refrigerant in contact with the inner wall 13b of the reserve tank be opposite to each other as shown in this figure. This is because heat radiation can be efficiently performed.

In addition, the heat-receiving fins 13c, or the heat-receiving plate 13h and the connecting body 13g is/are preferably fabricated of highly thermal conductive metallic material, or may be fabricated by casting, such as die casting, that can be easily adapted to a complicated shape.

### Third Embodiment

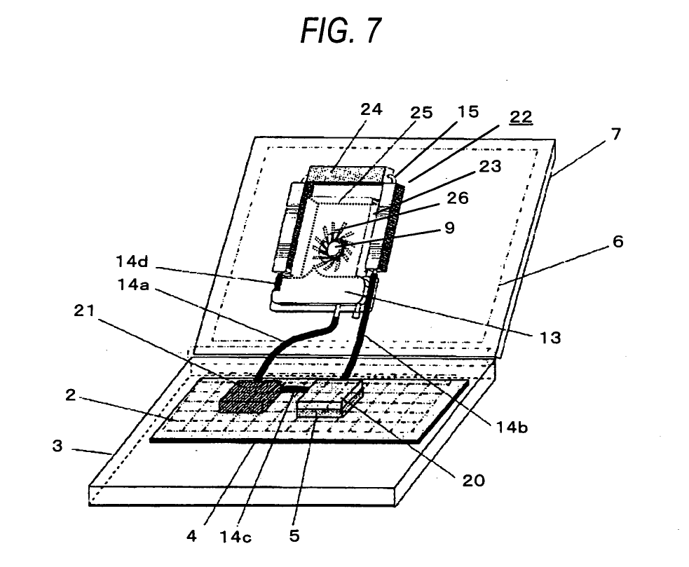

FIG. 7 illustrates the entire structure of an electronic apparatus incorporating a cooling device according to a third embodiment of the invention. This figure shows a first housing 3 of the electronic apparatus having a keyboard 2 mounted on its top face, a heating element 5 having a particularly large calorific value, such as a CPU mounted on an electronic circuit board 4 that is received in the first housing 3 and on which electronic components, etc. are arranged, a second housing 7 of the electronic apparatus having a display device 6 that displays processing results by the CPU, a heat receiver 20 that comes into close contact with the heating element 5 to receive heat from the heating element 5 and exchanges heat with the liquid refrigerant to cool the heating element 5, and a pump 21 for circulating the liquid refrigerant through the cooling device. As the heat receiver 20, highly thermal conductive, metallic material, such as metal, including aluminum and copper, and alloy, are used, and as shown in this drawing, the heat receiver 20 and the pump 21, which are formed as separate parts, are connected to each other by a connecting pipe 14c.

In addition, the pump 21 is a Wesco-type vortex pump, though not shown, that includes a ring-like impeller having a number of grooved blades formed at its outer periphery and having a rotor magnet provided at its inner periphery, and a motor stator provided at the inner periphery of the rotor magnet, and that is driven by applying an electric current to the motor stator. This ring-like impeller is accommodated in a pump casing having a suction port and an exhaust port. A cylindrical portion is disposed between the motor stator and the rotor magnet in the pump casing, and the ring-like impeller is rotatably incorporated into the cylindrical portion. In addition, since the pump 21 has a small, flat and slim shape, the cooling device can be made smaller and slimmer.

A rear face of the display device 6 is provided with three radiators 22 that are arranged in the shape of the letter “U” to radiate the heat transported by the liquid refrigerant into the air. The three side faces of a fan case 23 that constitute side faces and a bottom of the fan casing are respectively provided with rectangular exhaust ports to blow air by a thin fan 9 that is accommodated within the fan case 23 slightly closer to the reserve tank 13 from the inner center of the fan case 23. The remaining side face of the fan case 23 is provided with an air-blowing path wall (not shown) to smoothly perform the flow of the air within the fan case 23. In this embodiment, the air-blowing path wall is formed by an outer wall of the reserve tank 13.

Here, since the radiator 22 needs to remove the heat from the liquid refrigerant in a comparatively narrow space at the rear face of the display device 5, the radiator is configured such that a plurality of heat radiation fins 24 fabricated of material, such as aluminum and copper, are provided in a U-shaped metal pipe 15 so as to obtain broader surface area. The pipe 15 and the heat radiation fins 24 constituting the radiator 22 is firmly combined together by welding, fitting or the like because it is necessary to maintain the conductivity of the heat from the pipe 15 to the heat radiation fins 24 well.

On the other hand, since a fan cover 25 constituting an upper portion of the fan casing is attached to an upper portion of the fan case 23 and a substantially circular suction port 26 is formed in the direction along a rotating shaft of the fan 9, the air sucked from a suction port 26 is exhausted in the direction orthogonal to the rotating shaft by a centrifugal force of the fan 9 that is surrounded by the radiator 22 disposed in the shape of the letter “U” and installed so as to be locate substantially in the center of the U-shaped radiator. Further, a motor-driving part to rotate the fan 9 is mounted on the bottom (not shown) of the fan case 23.

In addition, a suction port may be provided in the bottom of the fan case 23, and a rib may be provided on the suction port to form a mounting part and then a motor-driving part may be provided on the mounting part.

Moreover, the reserve tank 13 reserves a predetermined amount of liquid refrigerant in advance so as to compensate a decrease in volume of the liquid caused by permeation and evaporation of the moisture in the liquid refrigerant through connecting pipes 14a to 14d, such as flexible tubes, constituting channels thereof, and the reserve tank 13 is provided next to the fan case 23. Even if the liquid refrigerant is gasified and thus bubbles are included in the refrigerant, the reserve tank 13 has a gas-liquid separating part (not shown) built therein for the purpose of trapping the bubbles to prevent flow of the bubbles into the pump 21, and the reserve tank 13 is connected to a circulating path by the connecting pipes 14a and 14d, such as flexible tubes.

Here, since the fan cover 25 serves as both a member forming an air-blowing path of the fan 9 along with the side wall of the fan case 23 and an upper wall member of the reserve tank 13, the liquid refrigerant within the reserve tank is thermally connected to the fan cover 25. That is, since the air outside the cooling device sucked from the suction port 26 comes into direct contact with the fan cover 25 that is a member forming an air-blowing path of the fan 9 and heat radiation of the liquid refrigerant within the reserve tank 13 is performed by heat exchange in the fan cover, it is possible to finally radiate heat to the outside by blowing of the fan 9. As a result, a rise in temperature of the liquid refrigerant within the reserve tank 13 can be suppressed.

Here, although it is preferable that the fan case 23 and the fan cover 25 be made of highly thermal conductive metal in terms of an improvement in thermal connectivity, an improvement in diffusivity of heat to the second housing 7 having broad area, etc. However, for example, if a gas-liquid separating part that does not cause air lock is built therein, the structure of the fan case and the fan cover becomes more complicated. Thus, the fan case and the fan cover may be fabricated of resin material having good moldability and capable of coping with cost reduction.

### Fourth Embodiment

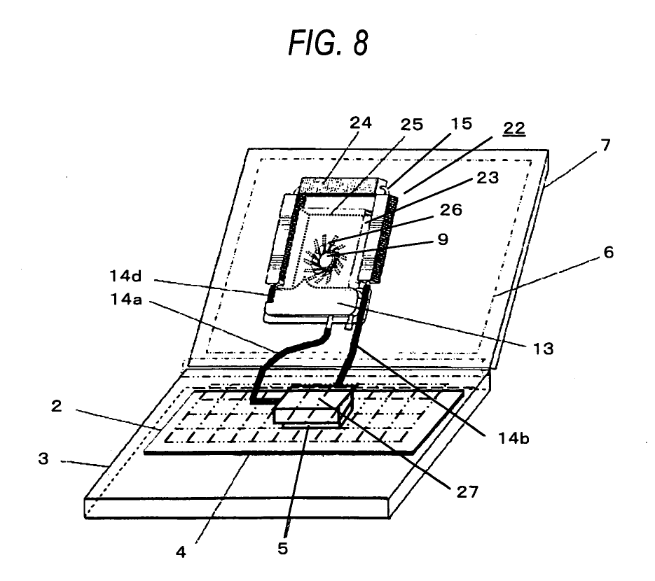

FIG. 8 illustrates the entire structure of an electronic apparatus incorporating a cooling device according to a fourth embodiment of the invention. The electronic apparatus includes a heat-receiver integrated pump 27 that is allowed to have a heat-receiving function by making the bottom face of a pump casing of a Wesco-type vortex pump flat and that serves as both functions of a pump and a heat receiver by providing liquid channels in the pump. This pump is directly placed on a heating element 5, such as a CPU. In this case, the casing of the heat-receiver integrated pump 27 is made of highly thermal conductive, metallic material, such as metal, including aluminum and copper, and alloy. Also, the pump can be easily placed on the top face of the heating element 5, such as a CPU, by forming the bottom face of the pump into a flat face appropriately according to the size of the heating element. Accordingly, sufficient heat transfer can be performed. Although the structures and operational effects of other radiating parts, such as a radiator 22, a fan 9 and a reserve tank 13, are the same as those of The third embodiment, the heat-receiver integrated pump 27 is used as a heat receiver and a pump. Thus, the number of components can be reduced and thus the whole cooling device can be more easily made small. As a result, mounting of the components to a narrow space within an electronic apparatus is also possible.

In addition, in the above description of the embodiments, the arrangement and number of each of the main components of the invention, i.e., the heat receiver, the pump or the heat-receiver integrated pump, if the heat receiver and the pump are integrated together, the radiator, the fan, the fan casing, and the reserve tank, or the method of thermally connecting the liquid refrigerant within the reserve tank with the members forming an air-blowing path of the fan, may be appropriately set according to the arrangement space within an electronic apparatus in which the cooling device is to be incorporated, and the suction and exhaust directions of the fan. The application of the invention is not limited to the structures as shown in the embodiments.

For example, when the reserve tank constitutes a portion of a member forming the fan casing as an air-blowing path of the fan, not only the reserve tank may be disposed in the peripheral direction of the fan as in this embodiment, but also the reserve tank may be changed to the base where a fan-driving part is to be placed, and may be disposed below the fan, or the reserve tank may be changed to the fan cover and may be disposed above the fan. Further, the reserve tank may be disposed within the fan casing. Similarly, even when the reserve tank constitutes a portion of a radiator or a duct as an air-blowing path of the fan, the arrangement and connecting method may be appropriately set in consideration of the space or heat radiation property within an electronic apparatus in which the reserve tank is to be incorporated.

In addition, although the heat-receiver integrated pump has been described about the case in which a Wesco-type vortex pump is built, other types of pumps may be employed, for example, including a centrifugal pump in which radial projections are formed on the surface of an impeller and liquid refrigerant is delivered from the center of the impeller to the periphery thereof.

In addition, the reserve tank of the invention reduces heat storage performance of reserved liquid refrigerant so as td obtain a high heat radiation property, in addition to reserving liquid refrigerant in advance so as to compensate a decrease caused by evaporation of the moisture in the liquid refrigerant that is a purpose of a conventional reserve tank. Thus, the reserve tank can also be disposed between a heat receiver and a radiator that are thermally connected to a heating element. As a result, the degree of freedom in designing the cooling device can be enhanced.

Even if liquid refrigerant is gasified and thus bubbles are included in the refrigerant, the pump or the heat-receiver integrated pump may have a gas-liquid separating part (not shown) built therein in order to trap the bubbles to prevent flow of the bubbles into the pump.

Moreover, in the above embodiments, the centrifugal fan in which the suction direction and the air-blowing direction are orthogonal to each other is used as the type of the fan. However, an axial-flow fan in which the suction direction and the air-blowing direction are the same direction may be used in order to further increase air volume. In this case, it is preferable that the liquid refrigerant within the reserve tank be thermally connected to the radiator, or a separately-provided duct, etc in relation to the air to be blown. Further, an outer frame of the axial-flow fan may be formed by the reserve tank.

The invention is applicable to a cooling device that cools a heating element while circulating liquid refrigerant, and an electronic apparatus including the cooling device.

What is claimed is:

1. A cooling device that circulates liquid refrigerant and takes heat from a heating element mounted on a board by exchange of heat with the liquid refrigerant to radiate the taken heat, the cooling device comprising:
a heat-receiving part, thermally connected to the heating element;
a pump, delivering toward a connecting pipe the liquid refrigerant on which heat exchange has been performed through the heat-receiving part;
a radiator, having a plurality of radiation fins that radiate heat by exchanging heat with the liquid refrigerant sent via the connecting pipe;
a fan, blowing air toward the radiator;
a fan casing, regulating an air-blowing direction of the fan; and
a reserve tank, reserving the liquid refrigerant,
wherein the liquid refrigerant within the reserve tank is thermally connected to a member forming an air-blowing path of the fan.

2. The cooling device according to claim 1,
wherein a highly thermal conductive metallic member is used for a thermal connection part between the liquid refrigerant within the reserve tank and the member forming an air-blowing path of the fan.

3. The cooling device according to claim 1,
wherein the reserve tank constitute a portion of the member forming an air-blowing path of the fan.

4. The cooling device according to claim 3,
wherein a partition plate to form a bypass channel for the liquid refrigerant is provided within the reserve tank.

5. The cooling device according to claim 3,
wherein heat-receiving fins are provided within the reserve tank, and the heat-receiving fins are thermally connected to the member forming an air-blowing path of the fan.

6. The cooling device according to claim 3,
wherein the flow directions of the air and liquid refrigerant that simultaneously touch all or a part of the member of the reserve tank to form an air-blowing path of the fan are opposite to each other.

7. An electronic apparatus, comprising the cooling device according to claim 1.

8. A cooling device comprising:
a pump, circulating liquid refrigerant;
a radiator, radiating the heat of the liquid refrigerant;
a circulating passage, connected to a reserve tank reserving the liquid refrigerant; and
a fan, having a fan casing,
wherein a portion of the fan casing is formed by an external surface of the reserve tank.

9. The cooling device according to claim 8,
wherein a partition plate to form a flow channel for the liquid refrigerant is provided within the reserve tank.

10. The cooling device according to claim 9,
wherein a partition plate to form a flow channel for the liquid refrigerant extending along the fan casing is provided within the reserve tank.

11. The cooling device according to claim 8, wherein a fan is provided within the reserve tank.

12. The cooling device according to claim 11, wherein the fan is provided inside the surface of the reserve tank to form the fan casing.

13. A blower, comprising:
a fan;
a driving part, driving the fan;
a fan casing, covering the fan and has an opening; and
a container with a port disposed in the fan casing.

14. A cooling device comprising:
a pump, circulating liquid refrigerant;
a radiator radiating the heat of the liquid refrigerant;
a circulating passage, connected to a reserve tank reserving the liquid refrigerant; and
a blower, blowing air toward the circulating passage,
wherein the blower includes a driving part driving a fan, a fan casing that cover the fan and has an opening, and a container with a port disposed in the fan casing.
